(19) United States
(12) Patent Application Publication
(10) Pub. No.: US 2026/0371794 A1
(43) Pub. Date: Nov. 19, 2026

(54) DUAL-BAND LIGHT EMITTING DIODE AND MANUFACTURING METHOD THEREOF

(71) Applicant: Taiwan-Asia Semiconductor Corporation, Hsinchu City (TW)

(72) Inventors: Ching-Yuan Tsai, Hsinchu City (TW); Hong-Ta Cheng, Hsinchu City (TW); Yu-Tong Hsiao, Hsinchu City (TW); Jia-Hua Yeh, Hsinchu City (TW)

(21) Appl. No.: 19/349,785

(22) Filed: Oct. 3, 2025

(30) Foreign Application Priority Data
May 19, 2025 (TW) 114118741

(51) Int. Cl. H10H 20/831; H10H 20/01; H10H 20/813

(52) U.S. Cl. CPC H10H 20/831; H10H 20/018; H10H 20/032; H10H 20/8131

(57) ABSTRACT

A dual-band light-emitting diode and a manufacturing method thereof are provided. The dual-band light-emitting diode comprises a first and a second epitaxial composite layers, a transparent conductive layer, and a plurality of first and second conductive plugs. The first epitaxial composite layer includes a first light-emitting layer with a first wavelength band, and the second epitaxial composite layer includes a second light-emitting layer with a second wavelength band, wherein the first wavelength band is no shorter than the second wavelength band. The transparent conductive layer is sandwiched between the first and second epitaxial composite layers. The first conductive plugs are disposed on a side of the transparent conductive layer and electrically connected to the first epitaxial composite layer. The second conductive plugs are disposed on an opposite side of the transparent conductive layer and electrically connected to the second epitaxial composite layer.

### CROSS-REFERENCES TO RELATED APPLICATIONS

This application claims the benefit of priority to Taiwanese Patent Application No. 114118741 filed on May 19, 2025, which is hereby incorporated by reference in its entirety.

### BACKGROUND OF THE INVENTION

### Field of the Invention

The present invention relates to a dual-band light-emitting diode and a manufacturing method thereof, and more particularly to a dual-band short-wavelength infrared light-emitting diode and a manufacturing method thereof.

### Descriptions of the Related Art

Light-emitting diodes (LEDs) offer advantages such as high brightness, compact size, low power consumption, and long lifespan, making them widely used in lighting and display products. In recent years, LEDs have increasingly been incorporated into wearable devices. For instance, LEDs are utilized in wearable devices for non-invasive blood glucose monitoring, sparing users the discomfort of long-term invasive blood glucose testing.

Taking blood glucose monitoring as an example, several LED chips operating in the short-wavelength infrared (SWIR) range, such as those emitting at 1065 nanometers (nm), 1350 nm, and 1450 nm, have been integrated into blood glucose monitoring modules. To enhance measurement accuracy, blood glucose monitoring modules have begun incorporating two or more LED chips with different wavelength bands. These different wavelengths cater to the varying absorption characteristics of skin and blood for different light bands, thereby improving detection sensitivity.

Common multi-band blood glucose monitoring modules combine LED chips emitting at 1065 nm with those emitting at 1350 nm or 1450 nm. However, LEDs emitting at 1065 nm can only be epitaxially grown on gallium arsenide (GaAs) substrates, while LEDs emitting at 1350 nm and 1450 nm require indium phosphide (InP) substrates for epitaxial growth. Consequently, the LED packaging in multi-band blood glucose monitoring modules must integrate at least two different wavelength chips, necessitating increased packaging space to accommodate multiple LED chips. In view of this, there is an urgent need in the industry for an innovative light-emitting diode structure and manufacturing method to meet the requirements of wearable devices for both compactness and accuracy.

### SUMMARY OF THE INVENTION

The primary objective of the present invention is to provide a high-brightness dual-band light-emitting diode and a manufacturing method thereof, capable of simultaneously providing short-wavelength infrared light in two wavelength bands within a single light-emitting diode structure. This reduces the packaging volume of the light-emitting diode, thereby meeting the requirements of wearable devices for compactness and precise detection.

To achieve the above objective, the present invention provides a dual-band light-emitting diode comprising a first epitaxial composite layer, a second epitaxial composite layer, a transparent conductive layer, a plurality of first conductive plugs, and a plurality of second conductive plugs. The first epitaxial composite layer includes a first light-emitting layer with a first wavelength band, and the second epitaxial composite layer includes a second light-emitting layer with a second wavelength band, wherein the first wavelength band is no shorter than the second wavelength band. The transparent conductive layer is sandwiched between the first and second epitaxial composite layers, with the first epitaxial composite layer disposed on the second epitaxial composite layer. The plurality of first conductive plugs are disposed on a side of the transparent conductive layer adjacent to the first epitaxial composite layer and are electrically connected to the first epitaxial composite layer. The plurality of second conductive plugs are disposed on an opposite side of the transparent conductive layer adjacent to the second epitaxial composite layer and are electrically connected to the second epitaxial composite layer.

In one embodiment of the dual-band light-emitting diode of the present invention, the dual-band light-emitting diode further comprises a P-type electrode disposed on the transparent conductive layer and electrically connected to the first conductive plugs and the second conductive plugs via the transparent conductive layer respectively.

In one embodiment of the dual-band light-emitting diode of the present invention, the dual-band light-emitting diode further comprises a first N-type electrode and a second N-type electrode, wherein the first N-type electrode is disposed on the first epitaxial composite layer and electrically connected to the first light-emitting layer, and the second N-type electrode is disposed on the second epitaxial composite layer and electrically connected to the second light-emitting layer.

In one embodiment of the dual-band light-emitting diode of the present invention, the first epitaxial composite layer further comprises an N-type indium phosphide epitaxial layer and a P-type indium phosphide epitaxial layer, with the N-type indium phosphide epitaxial layer and the P-type indium phosphide epitaxial layer sandwiching the first light-emitting layer.

In one embodiment of the dual-band light-emitting diode of the present invention, each first conductive plug is a P-type zinc-doped gallium arsenide conductive plug sandwiched between the P-type indium phosphide epitaxial layer and the transparent conductive layer.

In one embodiment of the dual-band light-emitting diode of the present invention, the second epitaxial composite layer further comprises an N-type aluminum gallium arsenide epitaxial layer and a P-type aluminum gallium arsenide epitaxial layer, with the N-type aluminum gallium arsenide epitaxial layer and the P-type aluminum gallium arsenide epitaxial layer sandwiching the second light-emitting layer.

In one embodiment of the dual-band light-emitting diode of the present invention, each second conductive plug is a P-type carbon-doped gallium arsenide conductive plug sandwiched between the P-type aluminum gallium arsenide epitaxial layer and the transparent conductive layer.

In one embodiment of the dual-band light-emitting diode of the present invention, the total area of the first conductive plugs is 3.5% to 8% of the light-emitting area of the first light-emitting layer, and the total area of the second conductive plugs is 3.5% to 8% of the light-emitting area of the second light-emitting layer.

In one embodiment of the dual-band light-emitting diode of the present invention, the first wavelength band ranges from 1100 to 2000 nanometers (nm), and the second wavelength band ranges from 1000 to 1100 nanometers (nm).

In one embodiment of the dual-band light-emitting diode of the present invention, the thickness of the transparent conductive layer ranges from 3000 to 10000 angstroms (Å).

To achieve the above objective, the present invention provides a manufacturing method for a dual-band light-emitting diode, comprising the following steps: providing a first epitaxial composite layer formed on a first epitaxial growth substrate, the first epitaxial composite layer including a first light-emitting layer with a first wavelength band; providing a plurality of first conductive plugs disposed on the first epitaxial composite layer and electrically connected to the first epitaxial composite layer; providing a first transparent conductive layer formed on the first epitaxial composite layer and covering the first conductive plugs; providing a second epitaxial composite layer formed on a second epitaxial growth substrate, the second epitaxial composite layer including a second light-emitting layer with a second wavelength band, wherein the first wavelength band is no shorter than the second wavelength band; providing a plurality of second conductive plugs disposed on the second epitaxial composite layer and electrically connected to the second epitaxial composite layer; providing a second transparent conductive layer formed on the second epitaxial composite layer and covering the second conductive plugs; and bonding the first transparent conductive layer and the second transparent conductive layer, such that the first transparent conductive layer and the second transparent conductive layer are sandwiched between the first epitaxial composite layer and the second epitaxial composite layer, with the first epitaxial composite layer disposed on the second epitaxial composite layer.

In one embodiment of the method for manufacturing the dual-band light-emitting diode of the present invention, the method further comprises, after removing the first epitaxial growth substrate, performing a mesa etching on the first epitaxial composite layer to expose a portion of the first transparent conductive layer.

In one embodiment of the method for manufacturing the dual-band light-emitting diode of the present invention, the method further comprises providing a P-type electrode disposed on the exposed first transparent conductive layer and electrically connected to the first conductive plugs and the second conductive plugs via the first transparent conductive layer and the second transparent conductive layer, respectively.

In one embodiment of the method for manufacturing the dual-band light-emitting diode of the present invention, the method further comprises providing a first N-type electrode disposed on the first epitaxial composite layer and electrically connected to the first light-emitting layer.

In one embodiment of the method for manufacturing the dual-band light-emitting diode of the present invention, the method further comprises thinning the second epitaxial growth substrate.

In one embodiment of the method for manufacturing the dual-band light-emitting diode of the present invention, the method further comprises providing a second N-type electrode disposed on the thinned second epitaxial growth substrate and electrically connected to the second light-emitting layer.

In one embodiment of the method for manufacturing the dual-band light-emitting diode of the present invention, the step of providing a first epitaxial composite layer formed on a first epitaxial growth substrate comprises sequentially providing an N-type indium phosphide epitaxial layer, the first light-emitting layer, and a P-type indium phosphide epitaxial layer on an indium phosphide substrate.

In one embodiment of the method for manufacturing the dual-band light-emitting diode of the present invention, the step of providing a plurality of first conductive plugs comprises providing a plurality of P-type zinc-doped gallium arsenide conductive plugs sandwiched between the P-type indium phosphide epitaxial layer and the first transparent conductive layer.

In one embodiment of the method for manufacturing the dual-band light-emitting diode of the present invention, the step of providing a second epitaxial composite layer formed on a second epitaxial growth substrate comprises sequentially providing an N-type aluminum gallium arsenide epitaxial layer, the second light-emitting layer, and a P-type aluminum gallium arsenide epitaxial layer on a gallium arsenide substrate.

In one embodiment of the method for manufacturing the dual-band light-emitting diode of the present invention, the step of providing a plurality of second conductive plugs comprises providing a plurality of P-type carbon-doped gallium arsenide conductive plugs sandwiched between the P-type aluminum gallium arsenide epitaxial layer and the second transparent conductive layer.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1A to FIG. 1C illustrate schematic diagrams of manufacturing a light-emitting diode structure with a first wavelength band in one embodiment of the present invention;

FIG. 2A to FIG. 2B illustrate schematic diagrams of manufacturing a light-emitting diode structure with a second wavelength band in one embodiment of the present invention;

FIG. 3A to FIG. 3G illustrate schematic diagrams of manufacturing a dual-band light-emitting diode in one embodiment of the present invention;

FIG. 4 is a top view schematic diagram of a dual-band light-emitting diode in one embodiment of the present invention; and

FIG. 5 is a schematic diagram of process steps for manufacturing a dual-band light-emitting diode in one embodiment of the present invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

The present invention discloses a dual-band light-emitting diode and a manufacturing method thereof, aimed at accommodating two independently operable light-emitting diodes within a single package to individually or collectively provide light in different wavelength bands for various subsequent applications. The following embodiments specifically illustrate how to integrate two independent light-emitting diodes into a single package.

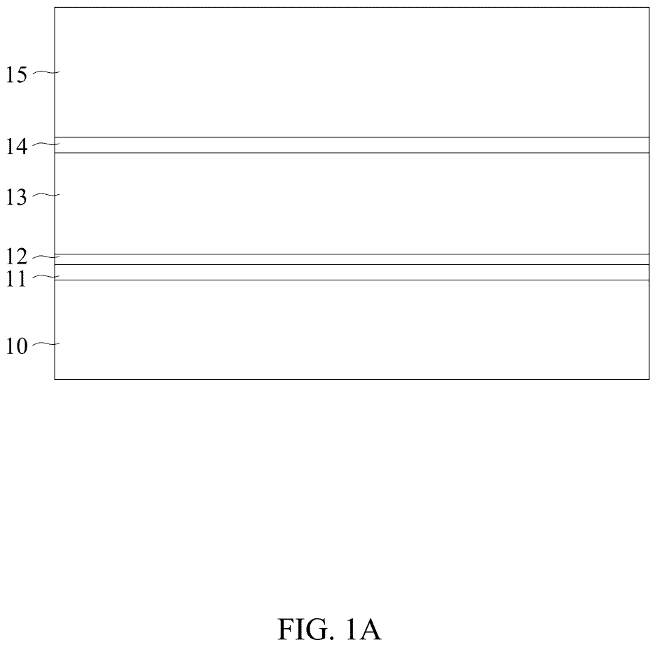

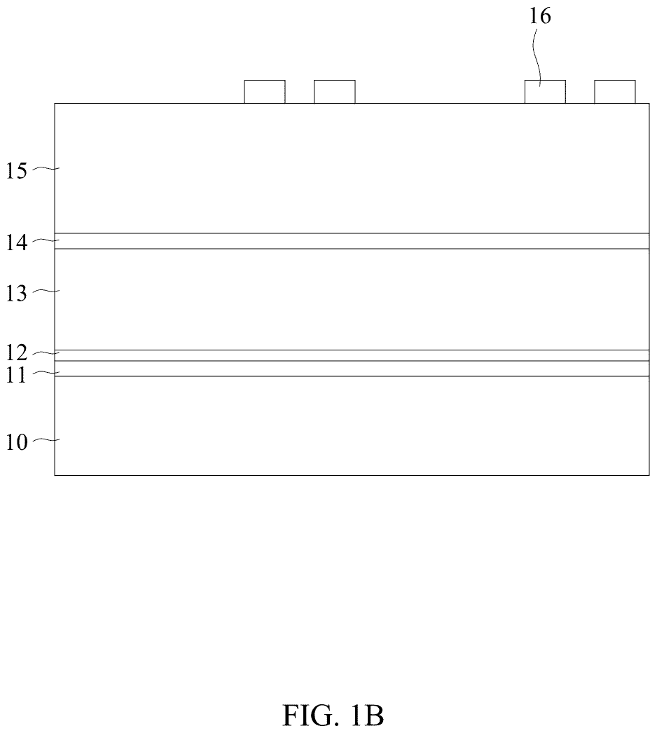

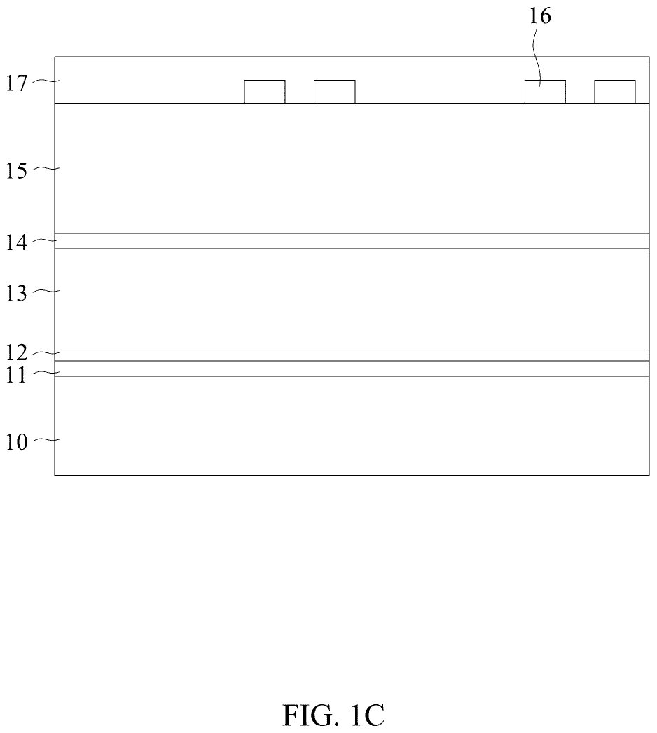

First, a light-emitting diode structure with a first wavelength band is prepared, where the first wavelength band may be, for example, but not limited to, 1100 to 2000 nanometers (nm). Referring to FIG. 1A, a buffer layer 11 and an N-type ohmic contact layer 12 are epitaxially grown on a first epitaxial growth substrate 10 using metal-organic chemical vapor deposition (MOCVD) or molecular beam epitaxy (MBE) techniques. Specifically, the first epitaxial growth substrate 10 is an indium phosphide (InP) substrate, but it is not limited thereto. The buffer layer 11 is an N-type indium phosphide (InP) epitaxial layer used to adjust lattice matching between the epitaxial growth substrate and the subsequent epitaxial composite layer, reducing stress caused by lattice mismatch in the subsequent epitaxial process, thereby improving the film quality of subsequent epitaxial layers.

Next, the N-type ohmic contact layer 12 is specifically an N-type indium gallium arsenide (InGaAs) epitaxial layer, with a lattice constant between that of indium phosphide (InP) and a multiple quantum well structure, thus also serving as a buffer layer to further adjust lattice matching for subsequent epitaxial layers. Additionally, the N-type indium gallium arsenide epitaxial layer optimizes carrier injection efficiency, with its bandgap adjustable based on the gallium and indium ratio, controlling electron and hole transport to ensure more carriers are effectively injected into the light-emitting layer, enhancing emission efficiency. Notably, the N-type ohmic contact layer 12 serves as the interface for ohmic contact with the N-type electrode, typically doped with sulfur(S), selenium (Se), or silicon (Si) at a doping concentration of 10¹⁸ to 10²⁰ cm⁻³. This concentration range helps reduce the Schottky barrier, achieving low-resistance ohmic contact.

Subsequently, a first epitaxial composite layer is grown on the N-type ohmic contact layer 12, comprising an N-type indium phosphide (InP) epitaxial layer 13, a first light-emitting layer 14, and a P-type indium phosphide epitaxial layer 15. The first light-emitting layer 14 is a multiple quantum well (MQW) structure made by indium gallium arsenide phosphide (InGaAsP) quaternary compound semiconductor, sandwiched between the N-type indium phosphide epitaxial layer 13 and the P-type indium phosphide epitaxial layer 15. Preferably, the N-type indium phosphide epitaxial layer 13 may be doped with silicon (Si), and the P-type indium phosphide epitaxial layer 15 may be doped with zinc (Zn). In this embodiment, the emission wavelength band of the multiple quantum well may range from 1100 to 2000 nm, preferably 1350 nm, 1450 nm, 1550 nm, or 1600 nm. It should be noted that the materials described in this embodiment are merely exemplary, and the present invention is not limited thereto. In practical applications, materials and compositions can be adjusted based on the emission wavelength, such as using aluminum indium arsenide (AlInAs) or indium gallium arsenide (InGaAs) for the epitaxial layers.

As shown in FIG. 1B, a compound semiconductor layer is epitaxially grown on the epitaxial composite layer. In this embodiment, the compound semiconductor layer is a P-type zinc-doped gallium arsenide (Zn-doped GaAs) epitaxial layer used for ohmic contact and vertical current conduction, with a thickness not exceeding 1 micrometer (μm), preferably 500 to 5000 angstroms (Å). Notably, the doping concentration of this zinc-doped gallium arsenide epitaxial layer ranges from 10¹⁸ to 10²⁰ cm⁻³, which helps reduce contact resistance to form an ohmic contact with the subsequent transparent conductive layer. Since the zinc-doped gallium arsenide epitaxial material may absorb light in the emission wavelength band of 1100 to 2000 nm of the first light-emitting layer, the present invention specifically patterns the zinc-doped gallium arsenide epitaxial layer to form a plurality of first conductive plugs 16 on the P-type indium phosphide epitaxial layer 15 of the first epitaxial composite layer. These first conductive plugs 16 are patterned and distributed according to the design pattern of the subsequent N-type upper electrode of the light-emitting diode, ensuring uniform vertical current distribution within the light-emitting diode during operation and minimizing brightness reduction due to light absorption. Referring to FIG. 1C, a first transparent conductive layer 17 is formed on the wafer surface, covering the first epitaxial composite layer, specifically covering the first conductive plugs 16 and the P-type indium phosphide epitaxial layer 15 of the first epitaxial composite layer. The first transparent conductive layer 17 is made of materials selected from indium tin oxide (ITO), aluminum zinc oxide (AZO), indium zinc oxide (IZO), nickel oxide, indium tin oxide, cadmium tin oxide, antimony tin oxide, and combinations thereof.

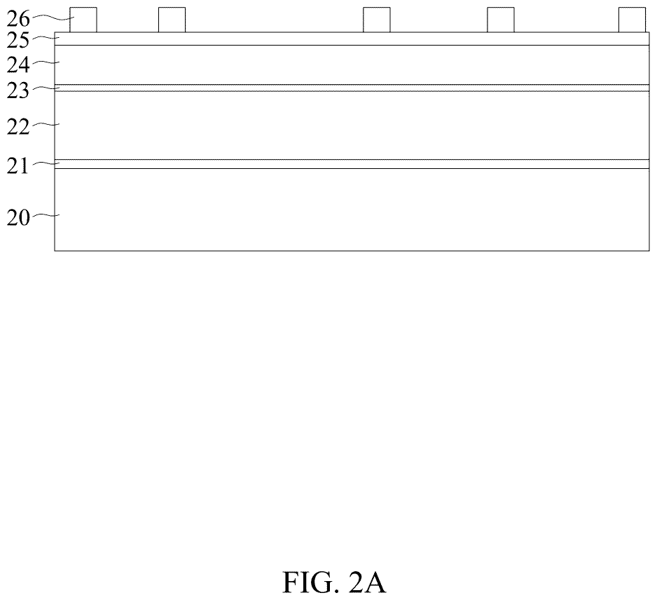

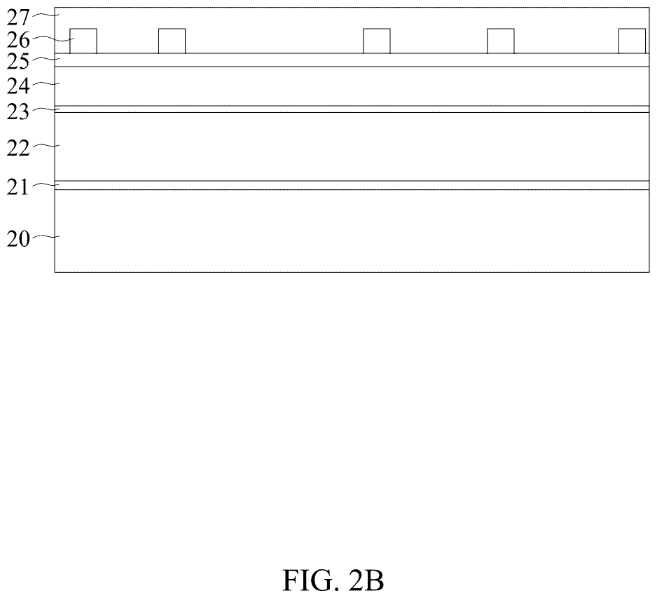

Next, a light-emitting diode structure with a second wavelength band is prepared, where the second wavelength band may be, for example, but not limited to, 1000 to 1100 nanometers (nm). Referring to FIG. 2A, a gallium arsenide (GaAs) substrate is used as a second epitaxial growth substrate 20. Subsequently, an N-type gallium arsenide layer 21 is formed on the gallium arsenide substrate as a buffer layer. A second epitaxial composite layer, such as a double heterostructure of aluminum gallium arsenide (AlGaAs), is then formed on the buffer layer. Specifically, in this embodiment, the second epitaxial composite layer comprises an N-type aluminum gallium arsenide (AlGaAs) epitaxial layer 22, a second light-emitting layer 23, and a P-type aluminum gallium arsenide (AlGaAs) epitaxial layer 24. The aluminum (Al) content in both the N-type aluminum gallium arsenide (AlGaAs) epitaxial layer 22 and the P-type aluminum gallium arsenide (AlGaAs) epitaxial layer 24 is 30%, with the remaining 70% being gallium arsenide (GaAs). The second light-emitting layer 23 is a multiple quantum well (MQW) structure made by indium gallium arsenide (InGaAs), with an emission wavelength band of 1000 to 1100 nm in this embodiment. In practical applications, the heterostructure epitaxial materials may also include aluminum indium gallium arsenide (AlInGaAs), aluminum gallium arsenide (AlGaAs), aluminum gallium arsenide phosphide (AlGaAsP), or indium gallium arsenide (InGaAs).

Referring to FIG. 2A, preferably, the second epitaxial composite layer further includes a P-type window layer, such as a P-type aluminum indium phosphide (AlInP) epitaxial layer 25, covering the P-type aluminum gallium arsenide epitaxial layer 24. This P-type aluminum indium phosphide epitaxial layer 25 has a high bandgap. The light absorption for the second wavelength band emitted by the second light-emitting layer 23 will be reduced for providing high transparency, and lateral current spreading capability will be enhanced. Subsequently, a P-type carbon-doped gallium arsenide (GaAs) epitaxial layer is epitaxially grown on the P-type aluminum indium phosphide epitaxial layer 25 for subsequent ohmic contact and vertical current conduction. The carbon doping concentration in this carbon-doped gallium arsenide epitaxial layer may be, but is not limited to, 4×10¹⁹ to 1.5×10²⁰ cm⁻³ to reduce contact resistance. Since the carbon-doped gallium arsenide epitaxial material may absorb light in the emission wavelength band of 1000 to 1100 nm of the second light-emitting layer, the present invention specifically patterns the P-type carbon-doped gallium arsenide epitaxial layer to form a plurality of second conductive plugs 26 on the P-type aluminum indium phosphide epitaxial layer 25 of the second epitaxial composite layer. Similarly, these second conductive plugs 26 are patterned and distributed according to the design pattern of the subsequent N-type and P-type electrodes of the light-emitting diode, ensuring uniform vertical current distribution within the light-emitting diode during operation and minimizing brightness reduction due to light absorption. Referring to FIG. 2B, a second transparent conductive layer 27 is formed by deposition, covering the second conductive plugs 26 and the P-type aluminum indium phosphide epitaxial layer 25. The material composition of the second transparent conductive layer 27 is the same as that of the first transparent conductive layer 17.

In another embodiment of the present invention, the second conductive plugs 26 may also use P-type carbon-doped gallium phosphide epitaxial material as the conductive plugs. However, when using P-type carbon-doped gallium phosphide epitaxial material as the second conductive plug material, it is preferable to dispose another P-type window layer, such as a gallium phosphide layer, between the second conductive plugs 26 and the P-type aluminum indium phosphide epitaxial layer 25 to adjust lattice mismatch. In other embodiments of the present invention, quaternary compound semiconductors, such as but not limited to aluminum gallium indium phosphide (AlGaInP), may also be used as the constituent material of the second epitaxial composite layer. Specifically, the second epitaxial composite layer may use aluminum gallium indium phosphide as both the second light-emitting layer and the N-type and P-type spacer layers sandwiching the second light-emitting layer. Additionally, the second conductive plugs 26 may similarly use P-type carbon-doped gallium phosphide epitaxial material, with a P-type aluminum indium phosphide layer and a P-type gallium phosphide layer preferably disposed between the second conductive plugs 26 and the P-type spacer layer. The P-type aluminum indium phosphide layer serves as a P-type cladding layer, providing a waveguide effect to enhance emission efficiency, while the P-type gallium phosphide layer serves as a P-type window layer to adjust lattice mismatch.

Summarizing the above, Table 1 below consolidates the content, clearly illustrating the epitaxial structure of the light-emitting diode with the second wavelength band according to the present invention. However, this table is for illustrative purposes only and is not intended to limit the present invention.

TABLE 1

epitaxial material

| | | quaternary |
|---|---|---|
| | Ternary Compound | compound |
| epitaxial structure | semiconductors | semiconductors |

| | | | |
|---|---|---|---|
| ohmic contact | GaP:C | GaAs:C | GaP:C |
| conductive plug | | | |
| P-type window layer | GaP | — | GaP |
| P-type cladding layer | AlInP | AlInP | AlInP |
| P-type spacer layer | AlGaAs | AlGaAs | AlGaInP |

| | | |
|---|---|---|
| light-emitting layer | AlInGaAs/AlGaAs/ | AlGaInP |
| | AlGaAsP/InGaAs | |

| | | | |
|---|---|---|---|
| N-type spacer layer | AlGaAs | AlGaAs | AlGaInP |
| N-type buffer layer | GaAs | GaAs | GaAs |
| epitaxial growth | GaAs | GaAs | GaAs |
| substrate | | | |

Note
“:” indicating doping

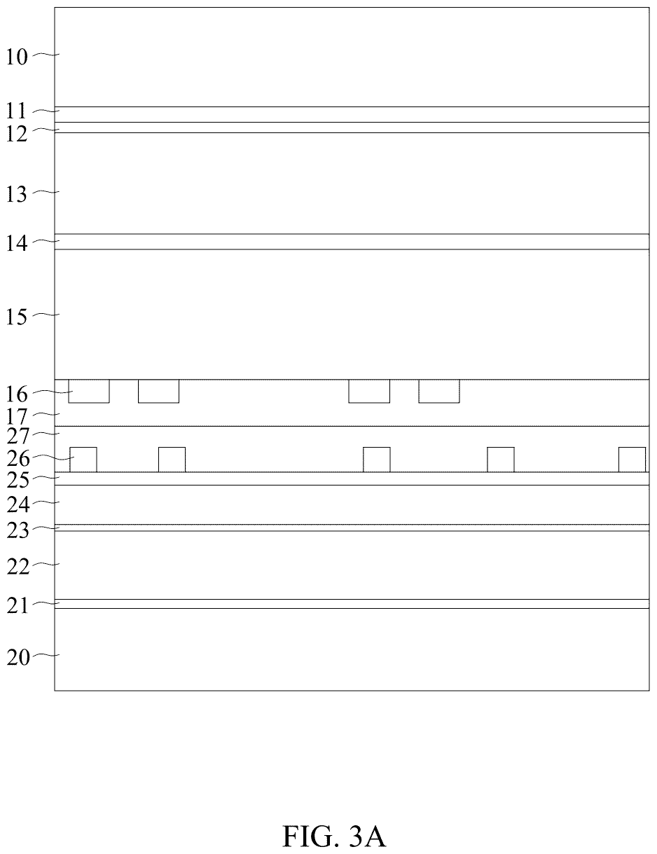

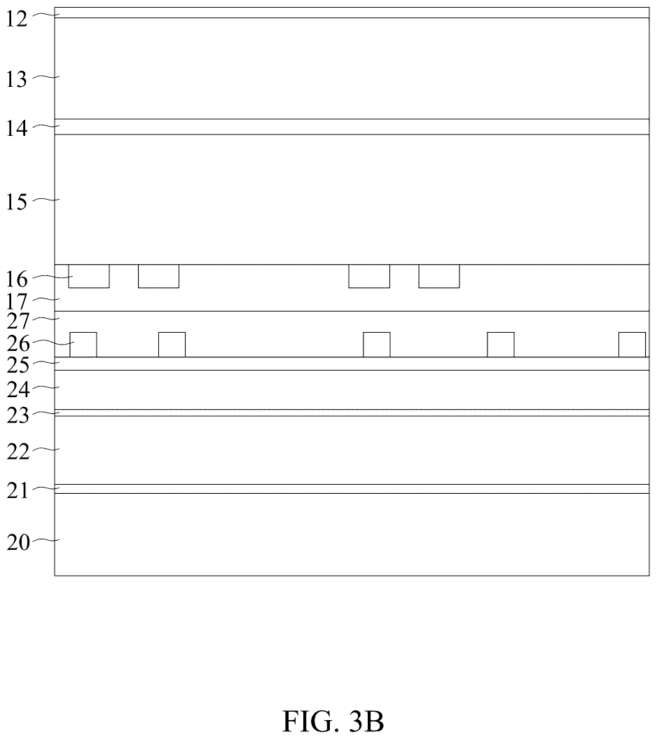

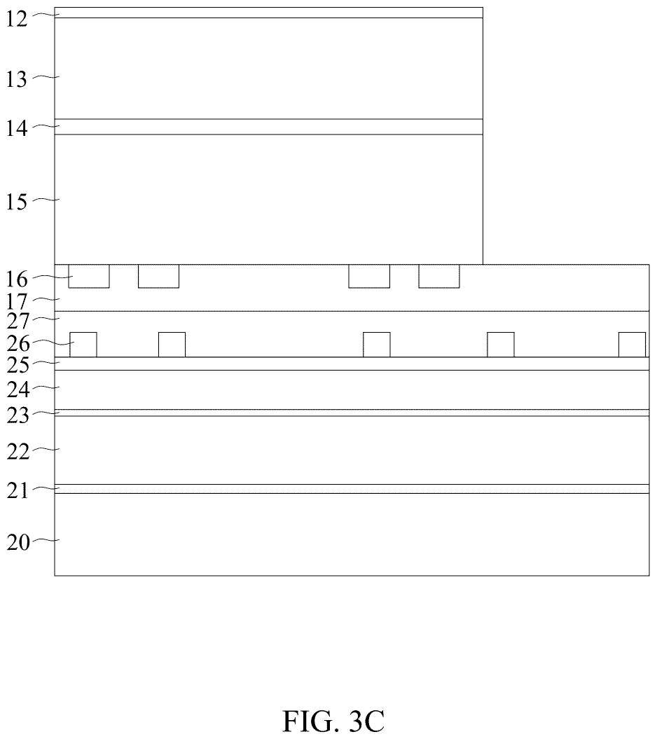

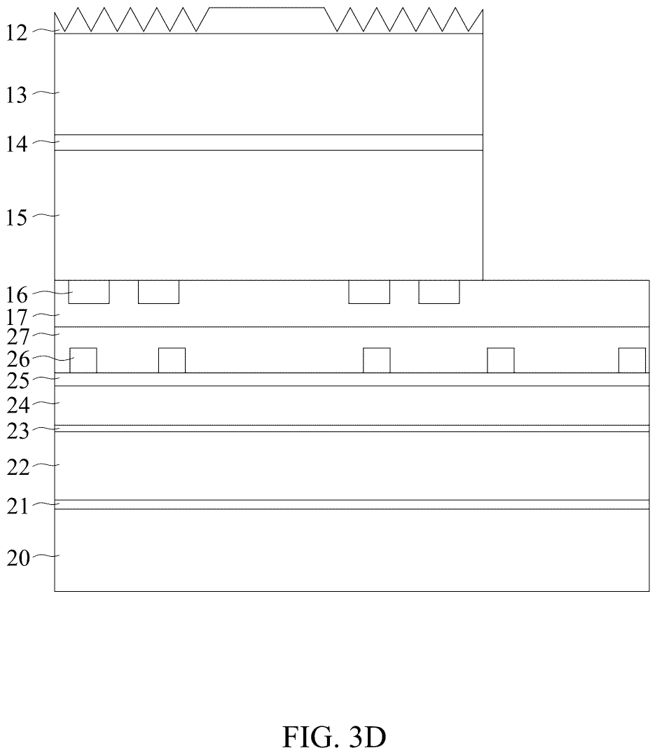

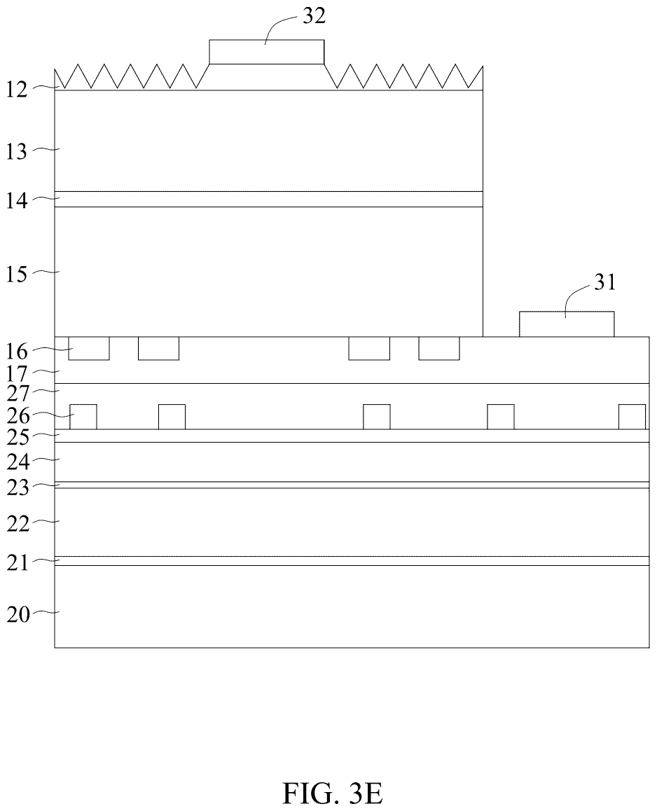

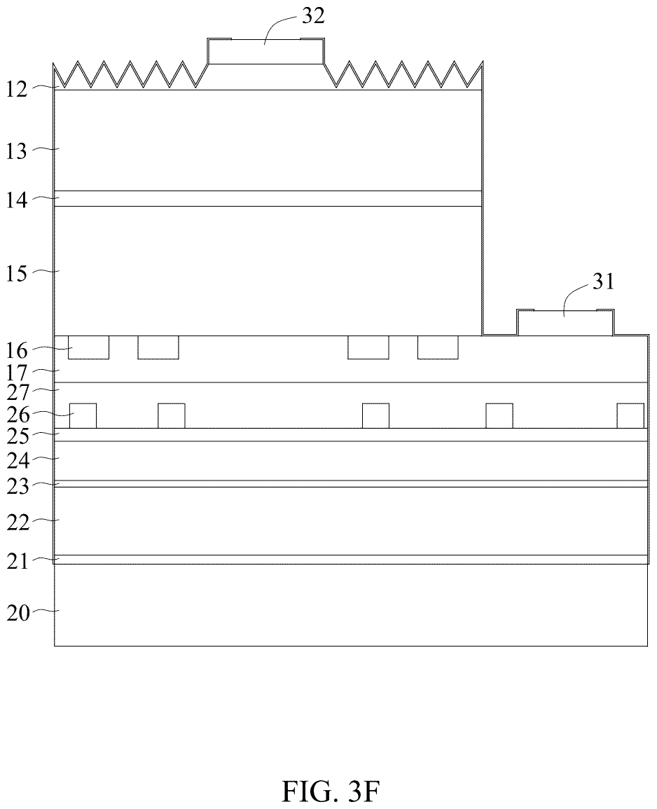

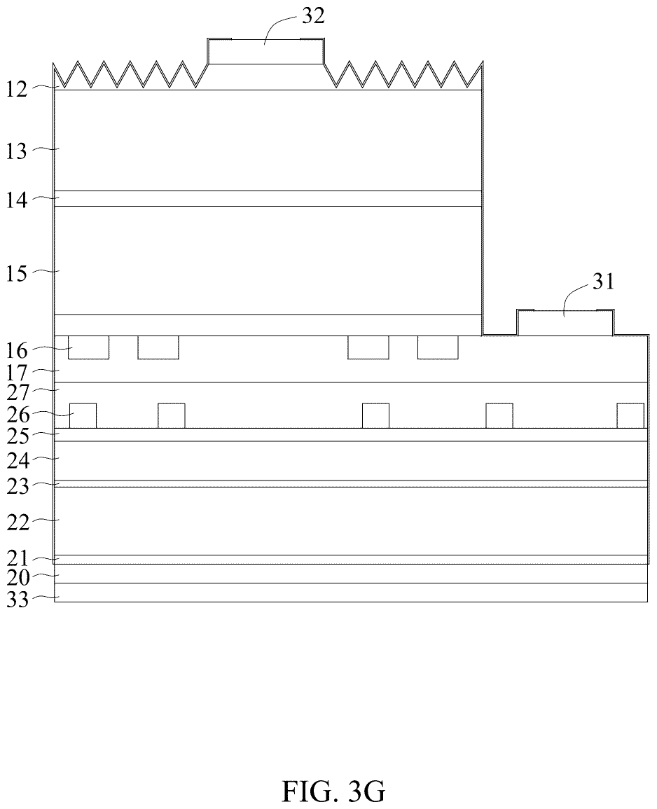

Referring to FIG. 3A, the first transparent conductive layer 17 on the first epitaxial growth substrate 10 is bonded at high temperature to the second transparent conductive layer 27 on the second epitaxial growth substrate 20, such that the first transparent conductive layer 17 and the second transparent conductive layer 27 are bonded to form a single transparent conductive layer, thereby bonding the two wafers. The total thickness of the bonded transparent conductive layer is preferably controlled within 3000 to 10000 angstroms (Å). As shown in FIG. 3A, the transparent conductive layer formed by bonding the first transparent conductive layer 17 and the second transparent conductive layer 27 is clearly sandwiched between the first and second epitaxial composite layers, enabling the light-emitting diode of the present invention to provide dual-band light emission within a single structure. Subsequently, the first epitaxial growth substrate 10 and the buffer layer 11 are removed together, with the second epitaxial growth substrate 20 serving as the main bottom structure of the dual-band light-emitting diode, as shown in FIG. 3B. A mesa etching process is then performed for etching portions of the N-type ohmic contact layer 12 and the first epitaxial composite layer to expose a flat surface of the first transparent conductive layer 17 for subsequent P-type electrode disposed thereon, as shown in FIG. 3C.

Referring to FIG. 3D, a roughening process is performed on the mesa to remove portions of the N-type ohmic contact layer 12. Subsequently, a metal deposition process is conducted to form a P-type electrode 31 on the exposed surface of the first transparent conductive layer 17 and a first N-type electrode 32 on the unroughened N-type ohmic contact layer 12, as shown in FIG. 3E. The P-type electrode 31 may be a metal stack, such as, but not limited to, a chromium-gold (CrAu) metal stack, a titanium-gold (TiAu) metal stack, or a chromium-titanium-gold (CrTiAu) metal stack, to provide good metal adhesion, ohmic contact, and high conductivity for the P-type electrode. The N-type electrode material may be, for example, but not limited to, a germanium-gold (GeAu) metal stack or a germanium-gold-nickel (GeAuNi) metal stack to ensure low contact resistance and good stability. Referring to FIG. 3F, a protective layer, such as a silicon dioxide (SiO₂) layer, is formed on the surface of the light-emitting diode device, except on the electrode surfaces designated for metal wire bonding.

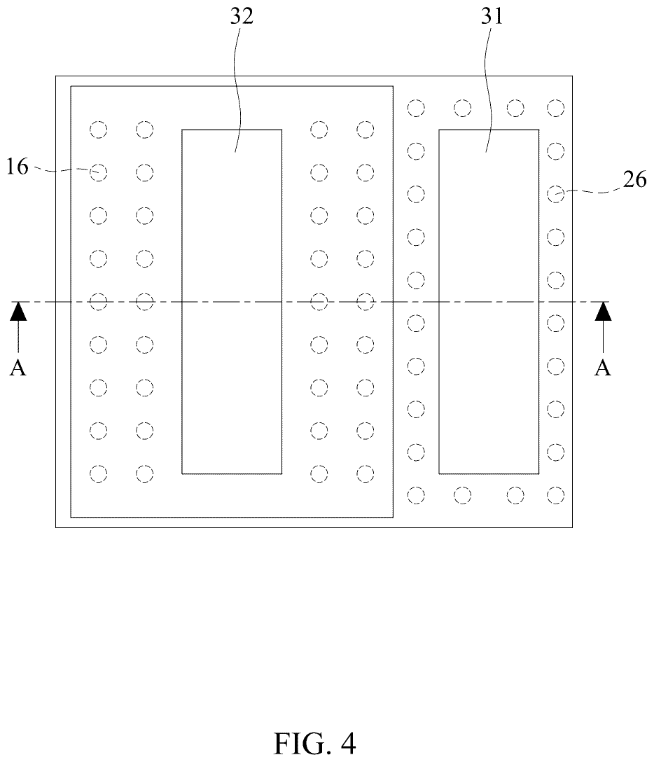

Referring to FIG. 3G, depending on the device design requirements, the second epitaxial growth substrate 20 is thinned for controlling the total height of the final light-emitting diode structure to 100 to 200 micrometers, but not limited thereto. For example, the second epitaxial growth substrate 20 may be completely removed to achieve a total height of the light-emitting diode structure of less than 100 micrometers. Finally, a second N-type electrode 33 is formed on the side of the thinned second epitaxial growth substrate 20, with the material of the second N-type electrode 33 being the same as that of the first N-type electrode 32, and is not repeated here. Referring to FIG. 4, a top view schematic diagram of the dual-band light-emitting diode in one embodiment of the present invention is shown. The cross-sectional view along the AA line in FIG. 4 corresponds to the cross-sectional view shown in FIG. 3G, clearly illustrating the plurality of first conductive plugs 16 and second conductive plugs 26 distributed around the first N-type electrode 32 and the P-type electrode 31, without overlapping in vertical positions, ensuring uniform current distribution and avoiding current crowding.

It should be specifically noted that the dual-band light-emitting diode disclosed in the present invention has two light-emitting layers with different wavelength bands. When the P-type electrode 31 and the first N-type electrode 32 are conducted, current flows through the first transparent conductive layer 17, the second transparent conductive layer 27, and the first conductive plugs 16 to activate the first light-emitting layer 14, thereby providing light in the first wavelength band. In this embodiment, this provides near-infrared light in the 1100 to 2000 nm range, such as 1350 nm or 1450 nm. On the other hand, when the P-type electrode 31 and the second N-type electrode 33 are conducted, current flows through the first transparent conductive layer 17, the second transparent conductive layer 27, and the second conductive plugs 26 to activate the second light-emitting layer 23, thereby providing light in the second wavelength band, such as 1065 nm near-infrared light. When the P-type electrode 31, the first N-type electrode 32, and the second N-type electrode 33 are conducted simultaneously, both the first light-emitting layer 14 and the second light-emitting layer 23 are activated, providing dual-band near-infrared light with both the first and second wavelength bands. This achieves the objective of providing dual-band light emission within a single light-emitting diode chip, meeting the requirements of wearable devices for compact and multi-band detection while also reducing related manufacturing costs.

In a preferred embodiment, during device design, the light-emitting epitaxial layer providing the longer wavelength band should be arranged at the top of the device structure, while the light-emitting epitaxial layer providing the shorter wavelength band should be arranged at the bottom. This ensures that light emitted from the lower light-emitting layer, when passing through the upper light-emitting epitaxial layer, is not absorbed by the smaller bandgap material above. Conversely, if the longer-wavelength light-emitting epitaxial layer is placed at the bottom and the shorter-wavelength light-emitting epitaxial layer is placed at the top, the longer-wavelength light emitted from the lower layer would be absorbed by the larger bandgap material of the upper short-wavelength layer, reducing the emission efficiency of the light-emitting device.

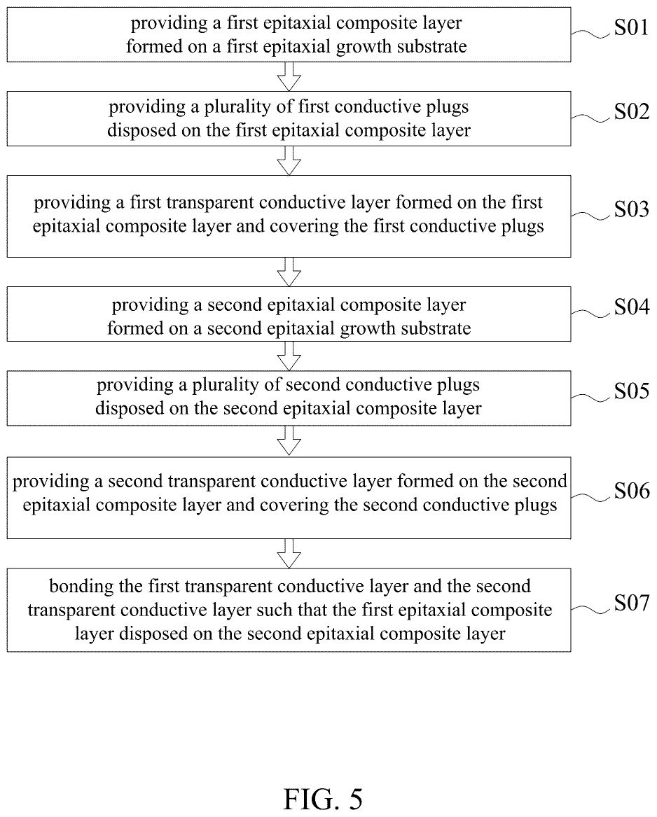

Referring to FIG. 5, a schematic flowchart illustrates the process for manufacturing the dual-band light-emitting diode of the present invention. In step S01, a first epitaxial composite layer is provided and formed on a first epitaxial growth substrate, wherein the first epitaxial composite layer includes a first light-emitting layer with a first wavelength band. In step S02, a plurality of first conductive plugs are provided and disposed on the first epitaxial composite layer and electrically connected to the first epitaxial composite layer. In step S03, a first transparent conductive layer is provided to be formed on the first epitaxial composite layer and covering the first conductive plugs. In step S04, a second epitaxial composite layer is provided and formed on a second epitaxial growth substrate, wherein the second epitaxial composite layer includes a second light-emitting layer with a second wavelength band, wherein the first wavelength band is no shorter than the second wavelength band. In step S05, a plurality of second conductive plugs are provided and disposed on the second epitaxial composite layer and electrically connected to the second epitaxial composite layer. In step S06, a second transparent conductive layer is provided and formed on the second epitaxial composite layer and covers the second conductive plugs. Finally, in step S07, the first transparent conductive layer and the second transparent conductive layer are bonded, such that the first transparent conductive layer and the second transparent conductive layer are sandwiched between the first epitaxial composite layer and the second epitaxial composite layer, with the first epitaxial composite layer disposed on the second epitaxial composite layer. The descriptions of the components in the aforementioned process steps can refer to the above content and are not repeated here.

The above embodiments are provided to illustrate the implementations of the present invention and to explain its technical features, and are not intended to limit the scope of the present invention. Any modifications or equivalent arrangements that can be easily accomplished by those skilled in the art fall within the scope of the present invention, and the scope of the present invention should be defined by the claims.

What is claimed is:

1. A dual-band light-emitting diode, comprising:
a first epitaxial composite layer including a first light-emitting layer with a first wavelength band;
a second epitaxial composite layer including a second light-emitting layer with a second wavelength band, wherein the first wavelength band is no shorter than the second wavelength band;
a transparent conductive layer sandwiched between the first epitaxial composite layer and the second epitaxial composite layer, and the first epitaxial composite layer disposed on the second epitaxial composite layer;
a plurality of first conductive plugs disposed on a side of the transparent conductive layer adjacent to the first epitaxial composite layer and electrically connected to the first epitaxial composite layer; and
a plurality of second conductive plugs disposed on an opposite side of the transparent conductive layer adjacent to the second epitaxial composite layer and electrically connected to the second epitaxial composite layer.

2. The dual-band light-emitting diode of claim 1, further comprising a P-type electrode disposed on the transparent conductive layer and electrically connected to the first conductive plugs and the second conductive plugs via the transparent conductive layer.

3. The dual-band light-emitting diode of claim 1, further comprising a first N-type electrode and a second N-type electrode, wherein the first N-type electrode is disposed on the first epitaxial composite layer and electrically connected to the first light-emitting layer, and the second N-type electrode is disposed on the second epitaxial composite layer and electrically connected to the second light-emitting layer.

4. The dual-band light-emitting diode of claim 1, wherein the first epitaxial composite layer further comprises an N-type indium phosphide epitaxial layer and a P-type indium phosphide epitaxial layer, with the N-type indium phosphide epitaxial layer and the P-type indium phosphide epitaxial layer sandwiching the first light-emitting layer.

5. The dual-band light-emitting diode of claim 4, wherein each of the first conductive plugs is a P-type zinc-doped gallium arsenide conductive plug sandwiched between the P-type indium phosphide epitaxial layer and the transparent conductive layer.

6. The dual-band light-emitting diode of claim 1, wherein the second epitaxial composite layer further comprises an N-type aluminum gallium arsenide epitaxial layer and a P-type aluminum gallium arsenide epitaxial layer, with the N-type aluminum gallium arsenide epitaxial layer and the P-type aluminum gallium arsenide epitaxial layer sandwiching the second light-emitting layer.

7. The dual-band light-emitting diode of claim 6, wherein each of the second conductive plugs is a P-type carbon-doped gallium arsenide conductive plug sandwiched between the P-type aluminum gallium arsenide epitaxial layer and the transparent conductive layer.

8. The dual-band light-emitting diode of claim 1, wherein the total area of the first conductive plugs is 3.5% to 8% of the light-emitting area of the first light-emitting layer, and the total area of the second conductive plugs is 3.5% to 8% of the light-emitting area of the second light-emitting layer.

9. The dual-band light-emitting diode of claim 1, wherein the first wavelength band ranges from 1100 to 2000 nanometers (nm), and the second wavelength band ranges from 1000 to 1100 nanometers (nm).

10. The dual-band light-emitting diode of claim 1, wherein the thickness of the transparent conductive layer ranges from 3000 to 10000 angstroms (Å).

11. A manufacturing method for a dual-band light-emitting diode, comprising:
providing a first epitaxial composite layer formed on a first epitaxial growth substrate, the first epitaxial composite layer including a first light-emitting layer with a first wavelength band;
providing a plurality of first conductive plugs disposed on the first epitaxial composite layer and electrically connected to the first epitaxial composite layer;
providing a first transparent conductive layer formed on the first epitaxial composite layer and covering the first conductive plugs;
providing a second epitaxial composite layer formed on a second epitaxial growth substrate, the second epitaxial composite layer including a second light-emitting layer with a second wavelength band, wherein the first wavelength band is no shorter than the second wavelength band;
providing a plurality of second conductive plugs disposed on the second epitaxial composite layer and electrically connected to the second epitaxial composite layer;
providing a second transparent conductive layer formed on the second epitaxial composite layer and covering the second conductive plugs; and
bonding the first transparent conductive layer and the second transparent conductive layer, such that the first transparent conductive layer and the second transparent conductive layer are sandwiched between the first epitaxial composite layer and the second epitaxial composite layer, with the first epitaxial composite layer disposed on the second epitaxial composite layer.

12. The manufacturing method for a dual-band light-emitting diode of claim 11, further comprising, after removing the first epitaxial growth substrate, performing a mesa etching on the first epitaxial composite layer to expose a portion of the first transparent conductive layer.

13. The manufacturing method for a dual-band light-emitting diode of claim 12, further comprising providing a P-type electrode disposed on the exposed first transparent conductive layer and electrically connected to the first conductive plugs and the second conductive plugs via the first transparent conductive layer and the second transparent conductive layer, respectively.

14. The manufacturing method for a dual-band light-emitting diode of claim 11, further comprising providing a first N-type electrode disposed on the first epitaxial composite layer and electrically connected to the first light-emitting layer.

15. The manufacturing method for a dual-band light-emitting diode of claim 11, further comprising thinning the second epitaxial growth substrate.

16. The manufacturing method for a dual-band light-emitting diode of claim 15, further comprising providing a second N-type electrode disposed on the thinned second epitaxial growth substrate and electrically connected to the second light-emitting layer.

17. The manufacturing method for a dual-band light-emitting diode of claim 11, wherein the step of providing a first epitaxial composite layer formed on a first epitaxial growth substrate comprises sequentially providing an N-type indium phosphide epitaxial layer, the first light-emitting layer, and a P-type indium phosphide epitaxial layer on an indium phosphide substrate.

18. The manufacturing method for a dual-band light-emitting diode of claim 17, wherein the step of providing a plurality of first conductive plugs comprises providing a plurality of P-type zinc-doped gallium arsenide conductive plugs sandwiched between the P-type indium phosphide epitaxial layer and the first transparent conductive layer.

19. The manufacturing method for a dual-band light-emitting diode of claim 11, wherein the step of providing a second epitaxial composite layer formed on a second epitaxial growth substrate comprises sequentially providing an N-type aluminum gallium arsenide epitaxial layer, the second light-emitting layer, and a P-type aluminum gallium arsenide epitaxial layer on a gallium arsenide substrate.

20. The manufacturing method for a dual-band light-emitting diode of claim 19, wherein the step of providing a plurality of second conductive plugs comprises providing a plurality of P-type carbon-doped gallium arsenide conductive plugs sandwiched between the P-type aluminum gallium arsenide epitaxial layer and the second transparent conductive layer.
